(19) United States
(12) Patent Application Publication
(10) Pub. No.: US 2011/0186877 A1
(43) Pub. Date: Aug. 4, 2011

(54) LIGHT EMITTING DIODE WITH BONDED SEMICONDUCTOR WAVELENGTH CONVERTER

(76) Inventors: Michael A. Haase, St. Paul, MN (US); Thomas J. Miller, Woodbury, MN (US); Andrew J. Ouderkirk, Singapore (SG); Catherine A. Leatherdale, Woodbury, MN (US); Tommie W. Kelley, Shoreview, MN (US)

(21) Appl. No.: 12/995,655

(22) PCT Filed: Apr. 23, 2009
(86) PCT No.: PCT/US2009/041521

§ 371 Date: Apr. 26, 2011

Related U.S. Application Data
(60) Provisional application No. 61/059,073, filed on Jun. 5, 2008.

(51) Int. Cl. H01L 33/50; H01L 33/08; H01L 33/26; B82Y 40/00

(52) U.S. Cl. 257/89; 257/98; 438/46; 438/29; 977/888; 257/E33.061; 257/E33.005; 257/E33.037

(57) ABSTRACT

An electroluminescent device emits light at a pump wavelength. A first photoluminescent element covers first and second regions of the electroluminescent device and converts at least some of the pump light from the first region of the electroluminescent device to light at a first wavelength. A second photoluminescent element covers the second region of the electroluminescent device without covering the first region of the electroluminescent device and converts at least some of the light of the pump wavelength to light at a second wavelength different from the first wavelength. In some embodiments the first and second photoluminescent elements convert substantially all of the pump light incident from the first and second regions of the electroluminescent device respectively. An etch-stop layer may separate the first and second photoluminescent elements.

### FIELD OF THE INVENTION

The invention relates to light emitting diodes, and more particularly to a light emitting diode (LED) that includes a wavelength converter for converting the wavelength of light emitted by the LED.

### BACKGROUND

Wavelength converted light emitting diodes (LEDs) are becoming increasingly important for illumination applications where there is a need for light of a color that is not normally generated by an LED, or where a single LED may be used in the production of light having a spectrum normally produced by a number of different LEDs together. One example of such an application is in the back-illumination of displays, such as liquid crystal display (LCD) computer monitors and televisions. In such applications there is a need for substantially white light to illuminate the LCD panel. One approach to generating white light with a single LED is to first generate blue light with the LED and then to convert some or all of the light to a different color. For example, where a blue-emitting LED is used as a source of white light, a portion of the blue light may be converted using a wavelength converter to yellow light. The resulting light, a combination of yellow and blue, appears white to the viewer. The color (white point) of the resulting light, however, may not be optimum for use in display devices, since the white light is the result of mixing only two different colors.

### SUMMARY OF THE INVENTION

One embodiment of the invention is directed to a light emitting device that emits light at first and second wavelengths. The device includes an electroluminescent device that emits light at a pump wavelength. A first photoluminescent element covers a first region and a second region of the electroluminescent device. The first photoluminescent element is capable of converting at least some of the light at the pump wavelength incident from the first region of the electroluminescent device to light at a first wavelength. The device also includes a second photoluminescent element disposed between the first photoluminescent element and the electroluminescent device. The second photoluminescent element covers the second region of the electroluminescent device without covering the first region of the electroluminescent device. The second photoluminescent element is capable of converting at least some of the light of the pump wavelength incident from the second region of the electroluminescent device to light at a second wavelength different from the first wavelength.

Another embodiment of the invention is directed to a light emitting device capable of emitting light at first and second wavelengths. The device includes an electroluminescent device that emits light at a pump wavelength. A first photoluminescent element covers a first region of the electroluminescent device. The first photoluminescent device is capable of converting substantially all of the light at the pump wavelength incident from the first region of the electroluminescent device to light at the first wavelength. A second photoluminescent element covers a second region of the electroluminescent device. The second photoluminescent element is capable of converting substantially all of the light at the pump wavelength incident from the second region of the electroluminescent device to light at the second wavelength.

Another embodiment of the invention is directed to a semiconductor construction that has a first re-emitting semiconductor construction that is capable of converting light at a pump wavelength to light at a first wavelength different from the pump wavelength. The first re-emitting semiconductor construction is capable of being etched by a first etchant. An etch-stop layer is epitaxially grown with the first re-emitting semiconductor construction. The etch-stop layer is capable of resisting etching by the first etchant. A second re-emitting semiconductor construction is epitaxially grown on the etch-stop layer and is capable of converting light at the pump wavelength to light at a second wavelength different from the pump and first wavelengths. Both the first re-emitting semiconductor construction and the etch-stop layer are substantially transparent to the light at the second wavelength emitted by the second re-emitting semiconductor construction.

Another embodiment of the invention is directed to a method of forming a light conversion element. The method includes providing a semiconductor construction having a first re-emitting portion, a second re-emitting portion and an etch-stop layer between the first and second re-emitting portions. The first re-emitting portion, the etch-stop layer and the second re-emitting portion are epitaxially grown together. A first region is etched in the second re-emitting portion to expose the etch-stop layer. A first region of the etch-stop layer is etched while illuminating the etch stop layer to fluoresce at a first wavelength. The light at the first wavelength is detected and the etching of the first region of the etch-stop layer is terminated when light of the first wavelength is no longer detected.

Another embodiment of the invention is directed to a method of forming a multiwavelength light emitting diode (LED). The method includes attaching a first photoluminescent element to an LED. The first photoluminescent element is capable of producing light at a first wavelength when illuminated with pump light from the LED. Portions of the first photoluminescent element are then removed. A second photoluminescent element is attached over the first photoluminescent element. The second photoluminescent element is capable of producing light at a second wavelength, different from the first wavelength, when illuminated with pump light from the LED.

The above summary of the present invention is not intended to describe each illustrated embodiment or every implementation of the present invention. The following figures and detailed description more particularly exemplify these embodiments.

### BRIEF DESCRIPTION OF THE DRAWINGS

The invention may be more completely understood in consideration of the following detailed description of various embodiments of the invention in connection with the accompanying drawings, in which:

FIG. 1 schematically illustrates an embodiment of a wavelength-converted light emitting diode (LED) according to principles of the present invention;

FIG. 2 schematically illustrates an embodiment of a wavelength converter, according to principles of the present invention;

FIGS. 3A-3F schematically illustrate fabrication steps in the fabrication of one embodiment of a wavelength-converted LED;

FIG. 4 schematically illustrates another embodiment of a wavelength-converted LED;

FIGS. 5A and 5B schematically illustrate other embodiments of wavelength-converted LEDs according to principles of the present invention; and

FIGS. 6A-6D schematically illustrate fabrication steps in another embodiment of a wavelength-converted LED.

While the invention is amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the spirit and scope of the invention as defined by the appended claims.

### DETAILED DESCRIPTION

The present invention is applicable to light emitting diodes that use a wavelength converter that converts the wavelength of at least a portion of the light emitted by the LED at a given wavelength into two additional wavelengths. Herein, when light is said to be at a wavelength, it is to be understood that the light may have a range of wavelengths, with the particular wavelength being a peak wavelength within the range of wavelengths. For example, where it is stated that light has a wavelength of λ, it should be understood that the light may comprise a range of wavelengths having λ as the peak wavelength of the range of wavelengths.

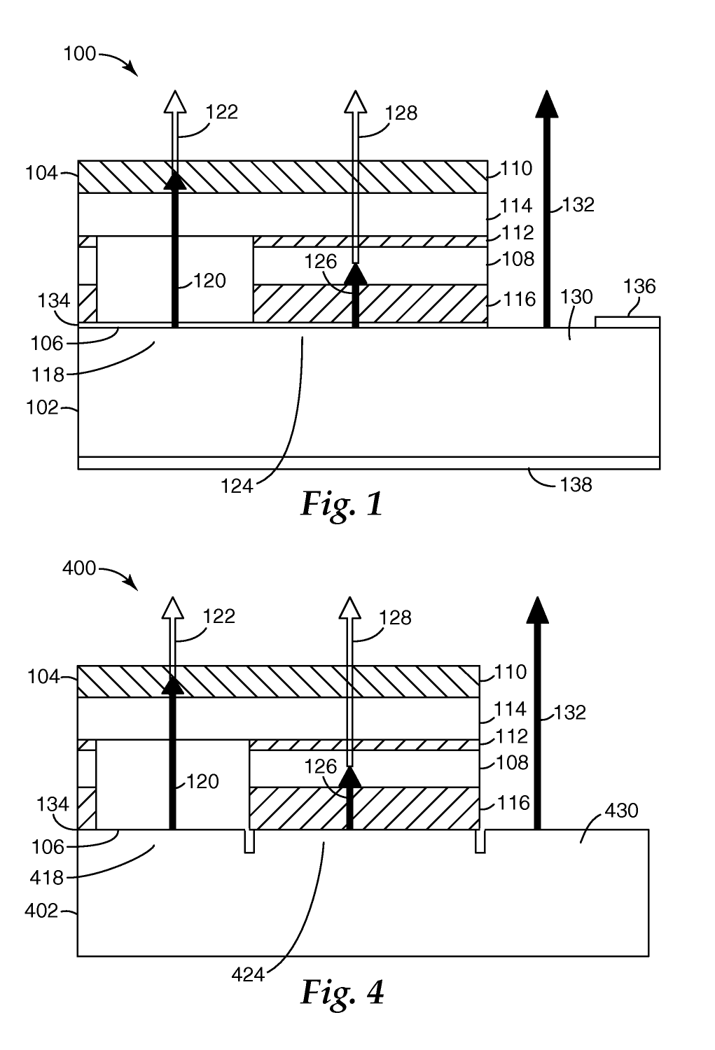

An example of a wavelength-converted LED device 100 according to a first embodiment of the invention is schematically illustrated in FIG. 1. The device 100 includes an LED 102, which is a type of electroluminescent device. A semiconductor wavelength converter 104 is attached to the upper surface 106 of the LED 102. The converter 104 is able to generate light at least two different wavelengths, λ1 and λ2, by converting light, at wavelength λp, received from the LED 102. The converter 104 is formed in a stack that includes a first photoluminescent element 108 positioned closer to the LED 102 than the second photoluminescent element 110. A photoluminescent element is a semiconductor structure that produces light at one characteristic wavelength when illuminated by light at another, generally shorter, characteristic wavelength. The first luminescent element generates light at λ1 when illuminated by light at λp from the LED 102. The second luminescent element generates light at λ2 when illuminated by light at λp from the LED 102. The two photoluminescent elements 108, 110 are separated by an etch-stop layer 112 and a window layer 114. Furthermore, a second window layer 116 may separate the first photoluminescent element from the LED 102.

Each semiconductor photoluminescent element 108, 110 includes at least one layer for absorbing light at λp from the LED 102, thus creating carrier pairs in the semiconductor, and at least one potential well layer, for example a quantum well layer, that collects the carriers, which recombine to emit light at a wavelength longer than λp. The wavelength, λ1, of light generated in the first photoluminescent element 108 is generally longer than that of the light, λ2, generated in the second photoluminescent element 110 so that the light at λ1 can pass through the second photoluminescent element 110. For example, where the LED 102 is a GaN-based LED, the light at λp is typically blue, with the first photoluminescent element 108 generating red light and the second photoluminescent element generating green light. Thus, the LED device 100 may be capable of emitting light of all three colors, red, green and blue, that are used in a display.

A first region 118 of the LED 102 is covered by only the second photoluminescent element 110. Light 120, having a wavelength λp, from the first region 116 of the LED 102 is incident on the second photoluminescent element 110 to generate light 122 at λ2. The second photoluminescent element 110 may absorb substantially all of the light 120 incident from the first region 116 of the LED 102, or may only absorb part of the incident light 120.

A second region 124 of the LED 102 is covered by both the first and second photoluminescent elements 108, 110. Light 126, having a wavelength λp, from the second region 124 of the LED 102 is incident on the first photoluminescent element 108, thus generating light 128 at λ1. The first photoluminescent element 108 may absorb substantially all the light 126 incident from the second region 124 of the LED 102. The light 128 at λ1 is substantially transmitted through the second photoluminescent element 110 and out of the wavelength converter 104.

A third region 130 of the LED 102 is not covered by either the first or second photoluminescent elements 108, 110. Thus light 132 at λp can pass directly out of the wavelength converter 104. It will be appreciated that the light from the LED 102 propagates in a number of different directions, as does the light from the first and second re-emitting regions 108, 110. Thus, the light 122, 128 and 132 at different wavelengths passes out of the LED device and becomes spatially mixed.

The wavelength converter 104 may be directly bonded to the LED 102 or may optionally be attached using a bonding layer 134. The use of a bonding layer 134 is discussed in greater detail in U.S. Patent Application Ser. No. 60/978,304, filed Oct. 8, 2007, and direct bonding of a wavelength converter 104 to an LED 102 is described in U.S. Patent Application Ser. No. 61/012,604, filed Dec. 10, 2007. Electrodes 136 and 138 may be provided on either side of the LED 102 to provide a driving current for the LED 102. The LED device 100 may also be provided with extraction features on one or more surfaces, for example as is discussed in Provisional Patent Application Ser. No. 60/978,304.5

While the invention does not limit the types of LED semiconductor material that may be used and, therefore, the wavelength of light generated within the LED, it is expected that the invention will be found to be useful at converting blue light. For example, an AlGaInN LED that produces blue light may be used with a wavelength converter that absorbs the blue light to produce red light and green light, with the resulting spatially mixed light appearing white.

A multilayered wavelength converter that may be used with the LED device 100 typically employs multilayered quantum well structures based on II-VI semiconductor materials, for example various metal alloy selenides such as CdMgZnSe. In such multilayered wavelength converters, the semiconductor wavelength converter is structured so that the band gap in portions of the structure is such that at least some of the pump light emitted by the LED is absorbed. The charge carriers generated by absorption of the pump light diffuse into quantum well layers, engineered to have a smaller band gap than the absorbing regions, where the carriers recombine and generate light at a longer wavelength. This description is not intended to limit the types of semiconductor materials or the multilayered structure of the wavelength converter.

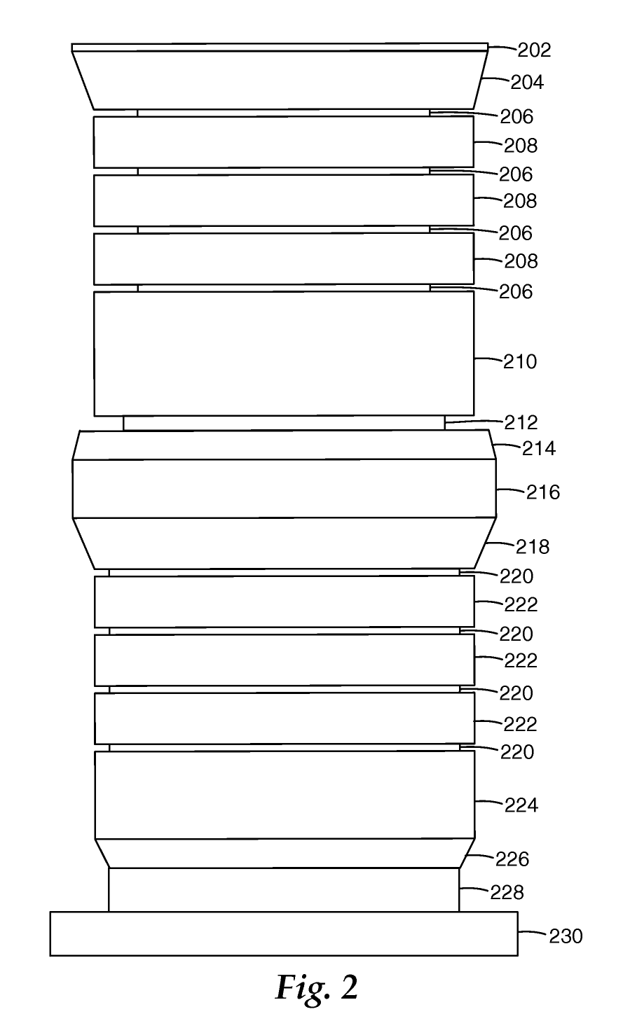

The band structure of an exemplary wavelength converter 200 is schematically illustrated in FIG. 2. The wavelength converter is epitaxially grown, for example using molecular beam epitaxy (MBE) or some other epitaxial technique. The different layers of the converter 200 are shown as an epitaxial stack, with the width of each layer being representative of the bandgap of the layer. The wavelength converter is typically grown on an InP substrate. A summary of the thickness, material, and bandgap for the various layers in an exemplary wavelength converter is presented in Table I below.

TABLE I
Summary of Exemplary Wavelength Converter Structure

| | | | Thickness | Bandgap |
|---|---|---|---|---|
| Layer no. | Description | Material | (μm) | (eV) |
| 202 | Bottom window | CdMgZnSe | 0.05 | 2.92 |
| 204 | Bandgap grading | CdMgZnSe | 0.22 | 2.92-2.48 |
| 206 | Red quantum well | CdZnSe | 0.0057 | 1.88 (emit at |
| | | | | 1.96) |
| 208 | Absorber for red | CdMgZnSe:Cl | 0.12 | 2.48 |
| | q.w. | | | |
| 210 | Absorber for red | CdMgZnSe:Cl | 0.64 | 2.48 |
| | q.w. | | | |
| 212 | Etch-stop layer | CdZnSe | 0.1 | 2.1 |
| 214 | Bandgap grading | CdMgZnSe | 0.15 | 2.48-2.92 |
| 216 | Middle window | CdMgZnSe | 0.35 | 2.92 |
| 218 | Bandgap grading | CdMgZnSe | 0.22 | 2.92-2.48 |
| 220 | Green quantum | CdZnSe | 0.0023 | 2.13 (emit at |
| | well | | | 2.25) |
| 222 | Absorber for | CdMgZnSe:Cl | 0.12 | 2.48 |
| | green q.w. | | | |
| 224 | Absorber for | CdMgZnSe:Cl | 0.5 | 2.48 |
| | green q.w. | | | |
| 226 | Graded absorber | CdMgZnSe | 0.13 | 2.48-2.35 |
| 228 | Buffer layer | GalnaAs | 0.2 | Lattice |
| | | | | matched to |
| | | | | InP |
| 230 | Substrate | InP | | |

A window layer is a semiconductor layer that is designed to be transparent to at least some of the light incident on the window layer. The bottom window layer 202 is the layer that is attached to the LED. A graded layer is one whose composition changes from one side to the other so as to provide a smooth transition in the band gap between adjacent layers. In the exemplary structure, the layer composition of the graded layer is changed by altering the relative abundances of Cd, Mg and Zn. A photoluminescent element includes a stack of absorbing layers alternating with potential well layers. Thus, the red photoluminescent element includes layers 206, 208 and 210, while the green photoluminescent element includes layers 220, 224 and 224. The etch-stop layer 212 is a layer that resists etching by the etchant used to etch the red photoluminescent element, so that the etch does not reach the green photoluminescent element.

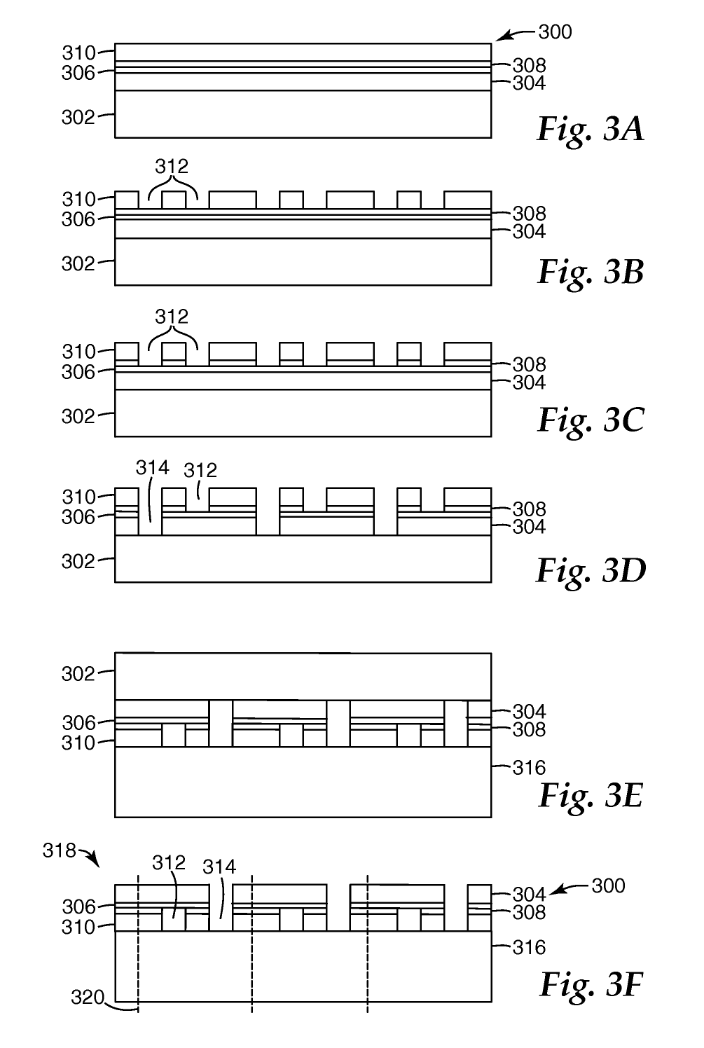

One approach to fabricating an LED device that includes a dual-wavelength converter is now discussed with reference to FIGS. 3A-3F. While the process is explained in general terms, the specific examples refer back to the dual wavelength converter described with reference to FIG. 2.

First, the stack of photoluminescent elements may be fabricated using conventional epitaxial growth techniques on a substrate, to produce a dual wavelength converter wafer 300, as schematically shown in FIG. 3A. The dual wavelength converter wafer 300 includes the substrate 302, a first photoluminescent element 304 for converting light to a first converted wavelength, a middle window layer 306, an etch stop layer 308 and a second photoluminescent element 310 for converting light to a second converted wavelength. Other layers, for example additional window layers, buffer layers and grading layers have been omitted for simplicity. In this process, the second photoluminescent layer 310 is the layer that is ultimately attached to the LED.

Using, for example, conventional photolithographic patterning, various regions 312 of the second photoluminescent layer 310 are etched up to the etch stop layer 308 using a suitable etchant. In the example from FIG. 2, the second luminescent layer 310 includes CdMgZnSe layers, in which case the etchant may be, for example a solution containing HCl or HBr.

The second photoluminescent layer 310 is designed to convert absorbed light to the second converted wavelength, which property may be used to monitor the etching process. The etch region 312 of the second photoluminescent layer 310 may be illuminated with light that is absorbed in the second photoluminescent layer 310 and the resulting converted light at the second converted wavelength detected. The light generated at the second converted wavelength may be detected by eye or by using any suitable detector, for example by a photodetector coupled with a filter or spectrum analyzer to reject light that is not at the second converted wavelength. The amount of light generated at the second converted wavelength falls off when the quantum wells of the second photoluminescent layer 310 have been removed from the etch region 312. When the second photoluminescent layer 310 is fully etched in region 312, the etch rate will slow or substantially stop at the surface of the etch-stop layer 308, to produce the wafer schematically shown in FIG. 3B.

In the specific example of the dual wavelength converter of FIG. 2, the etch region 312 is illuminated with blue or UV light from an LED, laser or other suitable light source, and the red converted light from the second photoluminescent layer 310 is detected. The etch-stop layer 308 fluoresces orange, so the emission of the red converted light ceases when the quantum wells of the second photoluminescent layer 310 are removed from the etch region 312.

The wafer 300 may then be rinsed before etching the etch-stop layer 308 in the etch region 312. The etch-stop layer 308 in the etch region 312 may then be removed using a second etchant. The etching process may be followed by monitoring the fluorescence of light from the etch-stop layer 308 resulting from illumination of the etch-stop layer 308 as it is being etched. Where the spectrum of the fluorescent light generated by the etch-stop layer 308 is different from the spectrum of the light generated by the underlying middle window layer 306 or the first photoluminescent layer 304 when illuminated by the light source, the fall off in fluorescence from the etch-stop layer 308 can be detected when the etch-stop layer 308 has been removed from the etch region 312. At this point the etching process can be halted, to produce the wafer schematically illustrated in FIG. 3C. Depending on the wavelength of light being used to illuminate the etch region 312, the illumination light either generates fluorescent light in the middle window layer 306 or generates light at the first converted wavelength in the first photoluminescent layer 304.

In the particular example of the dual wavelength converter of FIG. 2, the etch-stop layer 308 is formed of chlorine-doped CdZnSe and the second etch may be, for example, a solution of HBr/H₂O/Br₂ in the volume ratio 200/40/1. The CdZnSe etch-stop layer 308 may be illuminated with the same blue or UV light used to illuminate the second photoluminescent layer 310. When the illumination light is at or close to the same wavelength as light generated by the LED to which the wavelength converter is to be attached, the middle window 306 is substantially transparent to the illumination light and so green light is generated by the first photoluminescent layer once the etch-stop layer 308 has been removed by etching. Accordingly, the etching process can be halted once the emitted light has changed from orange to green.

After patterning, for example by photolithographic techniques, some regions 314 of the wafer 300 may be etched down to the substrate 302 by removing the middle window layer 306 and the first photoluminescent layer 304, resulting in the structure schematically illustrated in FIG. 3D. These layers may be etched using the same etchant as is used to etch the second photoluminescent layer 310.

The wafer 300 may then be attached to an LED wafer 316, for example via the use of an adhesive layer (not shown) or via direct bonding, to produce the structure schematically illustrated in FIG. 3E.

The substrate 302 may then be removed, for example by etching, for produce the structure schematically shown in FIG. 3F. In the example of the dual wavelength converter of FIG. 2, the substrate 302 is InP and can be removed by etching in a solution of 3 HCl:1 H₂O. A buffer layer of GaInAs (not shown) can be removed using an etchant of 40 g adipic acid: 200 ml H₂O:30 ml NH₄OH:15 ml H₂O₂. The shallow etch region 312 permits light from the LED wafer 316 to pass directly through the middle window layer 306 to the first photoluminescent region 304, to generate light at the first converted wavelength. Those regions where the second photoluminescent layer 310 are attached to the LED wafer 316 permit light from the LED wafer 316 to illuminate the second photoluminescent layer 310, to generate light at the second converted wavelength. The deep etch region 314 permits light from the LED wafer 316 to pass directly out of the wavelength converter.

The converted LED wafer 318, comprising the etched converter wafer 300 attached to the LED wafer 316, may be separated into individual converted LED devices by separating at the dashed lines 320. The converted LED wafer 318 may, for example, may be cut using a wafer saw, at the dashed lines 320 to produce separate wavelength converted LED devices. Other methods may be used for separating individual devices from the wafer 318, for example laser scribing and water jet scribing.

Another embodiment of a dual wavelength converted LED device 400 is schematically illustrated in FIG. 4. Several elements in this figure are similar to those discussed above with respect to FIG. 1 and have like identification numbers. The LED 402, however, contains individually addressable regions 418, 424 and 430. Electrodes used for activating each region 418, 424, 430 separately have been omitted to simplify the drawing, although it will be appreciated that each region 418, 424, 430 is provided with separate electrical connections. Specific activation of each of the regions 418, 424, 430 permits individual control of the amount of light produced by the device 400 at each of the three emitted wavelengths 122, 128, 132. As a result, the perceived shade of light emitted by the device 400 could be changed by changing the amount of light emitted at one of more of the wavelengths λp, λ1, λ2. For example, if the emission at the different wavelengths is balanced so that the perceived color is white, the current in the LED region 424 that produces red light could be reduced to produce a perceived cyan shade.

In another embodiment of a dual wavelength converted device, a dual converter may be patterned to match the pixelation of an array of pump LEDs, such that each individually addressable LED produces light at a single color, either through conversion or by passing through an etched region of the converter. Such a device may be used as a multi-color display.

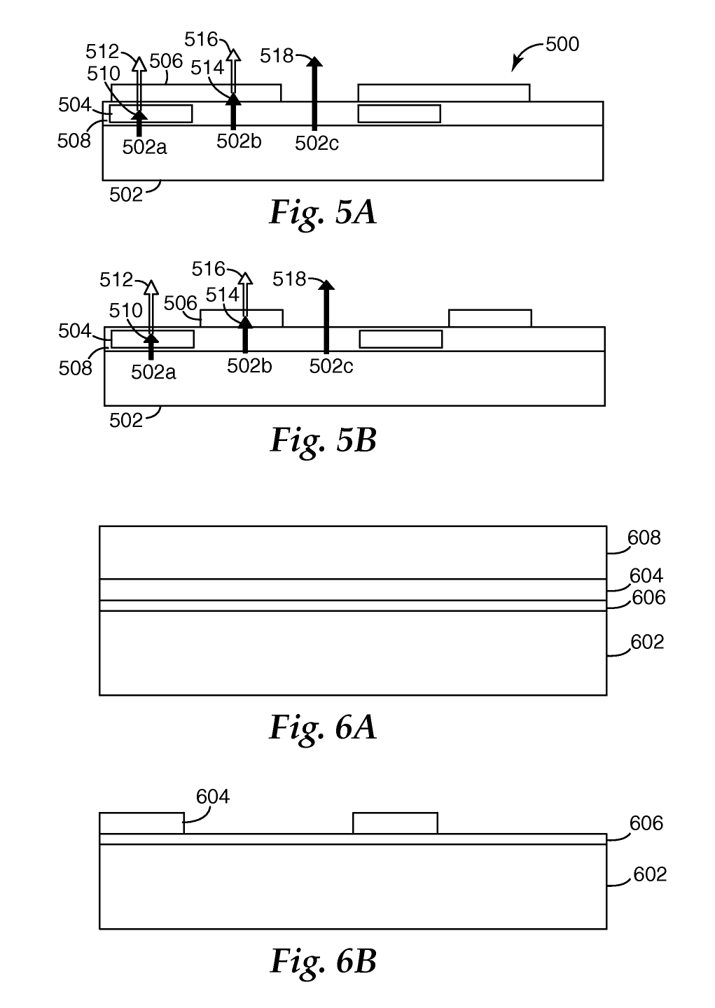

Another embodiment of a wavelength-converted LED 500 is schematically illustrated in FIG. 5A. In this embodiment, the wavelength-converted LED 500 includes an LED 502 on top of which are a first photoluminescent 504 and a second photoluminescent element 506. The first photoluminescent element 504 generates light at λ1 when illuminated by light at λp from the LED 502. The second luminescent element 506 generates light at λ2 when illuminated by light at λp from the LED 502. In this embodiment the two photoluminescent elements 504, 506 are grown separately from each other and may be attached together either before or after the first photoluminescent element 504 is attached to the LED 502. The first photoluminescent element 504 may be attached to the LED 502 using any suitable method, for example optical bonding as described above or through the use of an optical adhesive. In the illustrated example, an optical adhesive 508 is used to attach the first photoluminescent element 504 to the LED 502. Portions of the first photoluminescent element 504 above the second and third regions 502b, 502c of the LED 502 are removed, for example through etching. In the illustrated embodiment, the second photoluminescent element 506 is attached to the first photoluminescent element via optical adhesive 508. Portions of the second photoluminescent element 506 above the regions 502c of the LED 502 are removed, for example through etching.

Thus, the first photoluminescent element 504 converts light 510 at λp received from region 502a of the LED 502 to light 512 at λ1. The second photoluminescent element 506 converts light 514 at λp received from region 502b of the LED 502 to light 516 at λ2. Light 518 at λp from region 502c of the LED 502 is transmitted from the wavelength converted LED 500.

In another embodiment, schematically illustrated in FIG. 5B, portions of the second pohotoluminescent element 506 that lie above the first photoluminescent element 504 may also be removed, for example by etching.

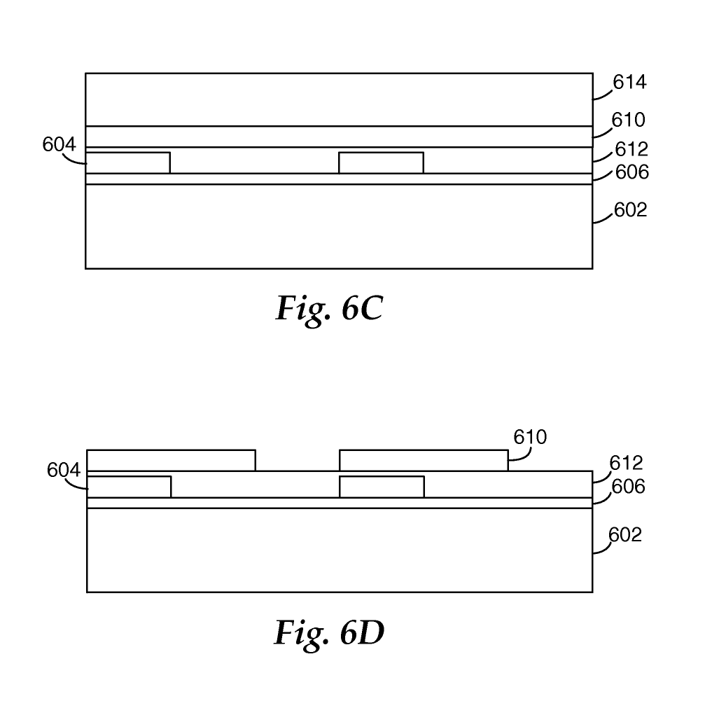

One possible approach for manufacturing the devices of FIG. 5A or 5B is now discussed with reference to FIGS. 6A-6D. A first photoluminescent layer 604 on a substrate 606 is attached to an LED device 602, as is schematically shown in FIG. 6A. The first photoluminescent layer 604 may be attached using a bonding agent such as an adhesive 608. The substrate 606 is removed and the photoluminescent layer 604 is patterned, for example using standard lithographic techniques, as is schematically shown in FIG. 6B.

A second photoluminescent layer 610 is attached to the first photoluminescent layer 604. The second photoluminescent layer 610 may be attached to the first photoluminescent layer 604 using an adhesive 612, or may be attached using a direct bond, as is schematically illustrated in FIG. 6C. The second photoluminescent layer 610 may be attached to a substrate 614 for ease of handling. In the case where an adhesive 612 is used, as in the illustrated example, the adhesive 612 may first be used to planarize the patterned first photoluminescent layer 604 before the addition of the second photoluminescent layer 610. The second photoluminescent layer may subsequently be patterned, as is schematically shown in FIG. 6D, for example using standard photolithographic techniques.

The present invention should not be considered limited to the particular examples described above, but rather should be understood to cover all aspects of the invention as fairly set out in the attached claims. Various modifications, equivalent processes, as well as numerous structures to which the present invention may be applicable will be readily apparent to those of skill in the art to which the present invention is directed upon review of the present specification. The claims are intended to cover such modifications and devices. For example, while the above description has discussed GaN-based LEDs, the invention is also applicable to LEDs fabricated using other III-V semiconductor materials, and also to LEDs that use II-VI semiconductor materials.

1. A light emitting device for emitting light at first and second wavelengths, comprising:
an electroluminescent device emitting light at a pump wavelength;
a first photoluminescent element covering a first region and a second region of the electroluminescent device, the first photoluminescent element capable of converting at least some of the light at the pump wavelength incident from the first region of the electroluminescent device to light at the first wavelength; and
a second photoluminescent element disposed between the first photoluminescent element and the electroluminescent device, the second photoluminescent element covering the second region of the electroluminescent device without covering the first region of the electroluminescent device, the second photoluminescent element capable of converting at least some of the light of the pump wavelength incident from the second region of the electroluminescent device to light at the second wavelength different from the first wavelength.

2. A device as recited in claim 1, wherein the first photoluminescent element comprises at least a first potential well and the second photoluminescent element comprises at least a second potential well.

3. A device as recited in claim 2, wherein the first photoluminescent element comprises a plurality of first potential wells disposed between absorbing semiconductor layers that absorb the light of the pump wavelength incident from the electroluminescent device, the first potential wells being capable of emitting light of the first wavelength, and wherein the second photoluminescent element comprises a plurality of second potential wells disposed between absorbing semiconductor layers that absorb the light at the pump wavelength incident from the electroluminescent device, the second potential wells being capable of emitting light at the second wavelength.

4. A device as recited in claim 1, wherein the first photoluminescent element is capable of converting substantially all of the light at the pump wavelength incident from the first region of the electroluminescent device to light at the first wavelength, and wherein the second photoluminescent element is capable of converting substantially all of the light at the pump wavelength incident from the second region of the electroluminescent device to light at the second wavelength.

5. A device as recited in claim 1, wherein the first and second photoluminescent elements comprise II-VI semiconductor materials.

6-8. (canceled)

9. A device as recited in claim 1, wherein the first photoluminescent element is grown epitaxially together with the second photoluminescent element.

10. A device as recited in claim 9, further comprising a window layer and an etch stop layer grown epitaxially between the first and second photoluminescent elements.

11. (canceled)

12. A device as recited in claim 1, further comprising a window layer epitaxially grown with the first photoluminescent element and disposed between the first photoluminescent element and the electroluminescent element, light at the pump wavelength from the first region passing through the window layer before being incident on the first luminescent element.

13. A device as recited in claim 1, wherein light at the second wavelength emitted by the second photoluminescent element and incident on the first photoluminescent element is substantially transmitted through the first photoluminescent element.

14-26. (canceled)

27. A semiconductor construction, comprising:
a first re-emitting semiconductor construction capable of converting light at a pump wavelength to light at a first wavelength different from the pump wavelength, the first re-emitting semiconductor construction capable of being etched by a first etchant;
an etch-stop layer epitaxially grown with the first re-emitting semiconductor construction, the etch-stop layer being capable of resisting etching by the first etchant; and
a second re-emitting semiconductor construction epitaxially grown on the etch-stop layer and capable of converting light at the pump wavelength to light at a second wavelength different from the pump and first wavelengths, both the first re-emitting semiconductor construction and the etch-stop layer being substantially transparent to the light at the second wavelength emitted by the second re-emitting semiconductor construction.

28. A construction as recited in claim 27, further comprising a substrate, wherein the first re-emitting semiconductor construction is epitaxially grown on the substrate.

29. A construction as recited in claim 28, wherein the substrate comprises indium phosphide (InP).

30. A construction as recited in claim 27, wherein the etch-stop layer is capable of fluorescing at a third wavelength having a wavelength shorter than the second wavelength.

31. A construction as recited in claim 27, further comprising a window layer epitaxially grown between the etch-stop layer and the first re-emitting semiconductor construction, portions of the second re-emitting semiconductor construction and the etch stop layer being removed to expose the window layer.

32. A method of forming a light conversion element, comprising:
providing a semiconductor construction having a first re-emitting portion, a second re-emitting portion and an etch-stop layer between the first and second re-emitting portions, the first re-emitting portion, the etch-stop layer and the second re-emitting portion being epitaxially grown together;
etching a first region in the second re-emitting portion to expose a region of the etch-stop layer;
etching the exposed region of the etch-stop layer while illuminating the etch stop layer to fluoresce at a first wavelength;
detecting the light of the first wavelength; and
terminating etching of the etch-stop layer when light of the first wavelength is no longer detected.

33. A method as recited in claim 32, wherein the providing the semiconductor construction comprises providing the semiconductor construction with the etch-stop layer formed of cadmium zinc selenide (CdZnSe) and etching the etch-stop layer comprises exposing the etch-stop layer to a solution of HBr/H₂O/Br₂.

34. A method as recited in claim 33, wherein the second re-emitting portion includes cadmium magnesium zinc selenide (CdMgZnSe), and etching the second re-emitting region comprises exposing the second re-emitting portion to a solution of at least one of HCl and HBr.

35. A method as recited in claim 32, wherein the first and second re-emitting portions each comprise an arrangement of CdZnSe quantum wells disposed between absorber layers formed of CdMgZnSe, the quantum wells of the first re-emitting portion arranged to emit green light and the quantum wells of the second re-emitting portion arranged to emit red light.

36. A method of forming a multiwavelength light emitting diode (LED), comprising:
attaching a first photoluminescent element to an LED, the first photoluminescent element being capable of producing light at a first wavelength when illuminated with pump light from the LED;
removing portions of the first photoluminescent element; and
attaching a second photoluminescent element over the first photoluminescent element, the second photoluminescent element being capable of producing light at a second wavelength, different from the first wavelength, when illuminated with pump light from the LED.

37. A method as recited in claim 36, further comprising removing portions of the second photoluminescent element by etching.

38-40. (canceled)

41. A method as recited in claim 36, wherein the first and second photoluminescent elements each comprise potential well structures formed in a II-VI semiconductor material.
